(19) United States
(12) Patent Application Publication
(10) Pub. No.: US 2004/0135627 A1
(43) Pub. Date: Jul. 15, 2004

(54) Current feedback circuit and feedback amplifier using the same

(75) Inventors: Keisuke Yamazato, Atsugi-shi (JP); Tomomitsu Oohara, Atsugi-shi (JP); Daisuke Suzuki, Atsugi-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: MITSUMI ELECTRIC CO., LTD., Tokyo (JP)

(21) Appl. No.: 10/746,613

(22) Filed: Dec. 24, 2003

(30) Foreign Application Priority Data
Dec. 27, 2002 (JP) 379897/2002

(51) Int. Cl. H03F 1/36

(52) U.S. Cl. 330/85

(57) ABSTRACT

An error amplifier stage (32) is supplied with an input signal from an input terminal (Vin) and a feedback signal produced by an output current/voltage converter stage (34) and amplifies the input signal with reference to the feedback signal to produce an amplified current signal which is delivered to a load driver stage (33). The error amplifier stage comprises an operational amplifier (6) of a voltage-controlled current-output type which is a transconductance amplifier having a transconductance gm. The transconductance amplifier includes a constant-current source and serves as a differential amplifying circuit based on the transconductance gm. A phase adjusting circuit for the transconductance amplifier is formed by a combination of a resistor (R10) and a capacitor (C10) connected in series between an output terminal of the transconductance amplifier and a ground potential.

This application claims priority to prior Japanese application JP 2002-379897, the disclosure of which is incorporated herein by reference.

### BACKGROUND OF THE INVENTION The present invention relates to a current feedback circuit for use in a feedback amplifier for producing an output voltage corresponding to an input signal.

For example, an existing current feedback circuit of the type is used in a BTL (balanced transformerless) circuit comprising two circuits reversed in phase to each other, i.e., a non-inverting amplifier and an inverting amplifier, and a coil load connected between output terminals of the non-inverting and the inverting amplifiers. The current feedback circuit converts a current flowing through a current detecting resistor inserted on an output side of the BTL circuit into a voltage, which is fed back as a feedback signal to the input side of the BTL circuit.

Such existing current feedback circuit will be described with reference to the drawing. As shown in FIG. 1, an input signal is supplied from a terminal Vin to both of a non-inverting amplifier 11 and an inverting amplifier 12. A coil load L10 is connected in series between output terminals OUT+ and OUT− of the non-inverting and the inverting amplifier 11 and 12, respectively.

The non-inverting amplifier 11 comprises an op rational amplifier 1 having a non-inverting input terminal supplied with the Input signal and an inverting Input terminal supplied with a reference voltage through a resistor R11. An output of the operational amplifier 1 is fed back through a resistor R12 to the inverting input terminal of the operational amplifier 1. Thus, a feedback circuit is formed through the resistor R12.

The inverting amplifier 12 comprises an operational amplifier 2 having an inverting input terminal supplied with the input signal through a resistor R13 and a non-inverting input terminal supplied with the reference voltage. An output of the operational amplifier 2 is fed back through a resistor R14 to the inverting input terminal of the operational amplifier 2. Thus, a feedback circuit is formed through the resistor R14.

At the output terminal OUT+of the non-inverting amplifier 11 and the output terminal OUT− of the inverting amplifier 12, a differential voltage between the outputs of the non-inverting amplifier 11 and the inverting amplifier 12 is extracted as an output voltage. The output voltage causes a driving current to flow through the coil load L10 connected between the output terminals OUT+ and OUT− of the non-inverting amplifier 11 and the inverting amplifier 12 so as to drive an external load,

Furthermore, between the output terminals OUT+ and OUT− of the non-inverting amplifier 11 and the inverting amplifier 12, a current detecting resistor R10 is connected in series to the coil load L10. An output current flowing through the current detecting resistor R10 is converted by a servo circuit 13 into a voltage value, which is fed back to the non-inverting input terminal of the non-inverting amplifier 11 and the inverting input terminal of the inverting amplifier 12 so as to control the input signal.

With such circuit structure as described above, it is not possible to avoid occurrence of a phase lag between the output voltage and the output current within a high frequency range under the influence of an inductance component of the coil load. Accordingly, those coils which can be connected as a load are limited.

In order to solve the above-mentioned problem, proposal has been made of another existing current feedback circuit, for example, in Japanese Patent Application Publication (JP-A) No. H10-256838. In the current feedback circuit disclosed in the publication, the output current flowing through the load is converted into the output voltage which is fed back through a phase compensation element to an amplifier stage for amplifying the input signal with reference to the output voltage.

The current feedback circuit disclosed in the above-mentioned publication will be described with reference to the drawing.

Referring to FIG. 2, a feedback amplifier with a current feedback circuit comprises an amplifier stage 23 including the above-mentioned BTL circuit. The feedback amplifier further comprises a preamplifier stage 21, an error amplifier stage 22, and an output current/voltage converter stage 24.

The preamplifier stage 21 illustrated in the figure includes an operational amplifier 3 which serves as an inverting amplifying circuit. Supplied with an input signal from an input terminal Vin, the preamplifier stage 21 pre-amplifies the input signal and sends a pre-amplified input signal to the error amplifier stage 22. The error amplifier stage 22 includes an operational amplifier 4 having a non-inverting input terminal connected to an output terminal of the preamplifier stage 21 and an inverting input terminal connected to an output terminal of the output current/voltage converter stage 24 through a resistor R24. The operational amplifier 4 has an output terminal connected to an input terminal of the amplifier stage 23 and to the inverting input terminal of the operational amplifier 4 through a resistor R23 and a capacitor C21 connected in series.

The amplifier stage 23 has the BTL circuit similar to that shown in FIG. 1. The output current/voltage converter stage 24 includes an operational amplifier 5 and forms a typical differential amplifying circuit in which a predetermined voltage is supplied to a non-inverting input terminal of the operational amplifier 5. The output current/voltage converter stage 24 converts the output current flowing through a current detecting resistor R10 of the current feedback circuit into the voltage, which is supplied through the resistor R24 to the inverting input terminal of the operational amplifier 4 in the error amplifier stage 22.

Thus, the error amplifier stage 22 serves to amplify the input signal with reference to the output voltage converted from the output current flowing through the current detecting resistor R10 of the current feedback circuit. The phase compensation element is formed by a series circuit of a resistor R23 and a capacitor C21 connected between the output terminal and the inverting input terminal of the operational amplifier 4.

In the existing current feedback circuit described above, the error amplifier stage for amplifying the input signal with reference to the output voltage converted from the output current flowing through the current detecting resistor uses the operational amplifier which forms a differential amplifier of a voltage-controlled voltage-output type. Therefore, the phase compensation element is applied to a feedback circuit for the operational amplifier. With this structure, it is required to provide the resistor for receiving the output voltage from the output current/voltage converter stage and to appropriately design the resistance value of the resistor for a transfer function.

### SUMMARY OF THE INVENTION

It is therefore an object of the present invention to provide a current feedback circuit, which is capable of adjusting a phase characteristic of the input signal and realizing a predetermined frequency band over a wide range, and preventing oscillation in an open-loop frequency characteristic with an ample phase margin, without using a feedback type operational amplifier in an error amplifier stage.

It is another object of the present invention to provide a feedback amplifier using the above-mentioned current feedback circuit.

According to the present invention, there is provided a feedback amplifier which is for producing an output voltage in response to an input signal and which comprises a preamplifier stage (31), an error amplifier stage (32), a load driver stage (33), and an output current/voltage converter stage (34). A combination of the output current/voltage converter stage (34) and the error amplifier stage (32) forms a current feedback circuit. The output current/voltage converter stage (34) converts a current obtained through a current detecting resistor (R10) inserted on an output side of the feedback amplifier into a voltage, which is supplied as a feedback signal to the error amplifier stage (32). The error amplifier stage (32) comprises an operational amplifier (6) of a voltage-controlled current-output type, a resistor (R31), and a capacitor (C31). The operational amplifier (6) has an inverting input terminal supplied with the feedback signal sent from the output current/voltage converter stage (34) and a non-inverting input terminal supplied with the input signal. The operational amplifier (6) produces an amplified current obtained by amplifying the input signal with reference to the feedback signal and sends the amplified current to the load driver stage (33) and to the resistor (R31) and the capacitor (C31), which are connected in series between an output terminal of the operational amplifier (6) and a ground potential.

As mentioned above, the error amplifier stage (32) uses the operational amplifier (6) comprising a differential amplifying circuit of the voltage-controlled current-output type for producing the amplified current obtained by amplifying the input signal with reference to the feedback signal. Therefore, when the input signal is amplified with reference to the feedback signal, the characteristic of the amplified current depends on a transconductance (transfer conductance) gm of the operational amplifier (6). One of the resistor (R31) and the capacitor (C31) connected in series as a series circuit is connected to the output terminal of the operational amplifier (6) and the other is connected to the ground potential so as to adjust the phase of the amplified current.

The operational amplifier (6) in the error amplifier stage (32) may be a transconductance amplifier which has a non-inverting input terminal supplied with the input signal through the preamplifier stage (31) and an inverting input terminal supplied with the feedback signal from the output current/voltage converter stage (34) and which produces a current corresponding to a voltage difference between the inverting input terminal and the non-inverting input terminal.

Thus, according to this invention, it is possible to adjust the phase characteristic of the input signal, to achieve a predetermined frequency band over a wide range, and to prevent oscillation in an open-loop frequency characteristic with an ample phase margin, without using a feedback type operational amplifier. Furthermore, it is possible to contribute to the decrease in number of terminals and the miniaturization of an integrated circuit including the feedback amplifier and a package accommodating the integrated circuit because one end of the series circuit of the resistor (R31) and the capacitor (C31) is connected to the ground terminal.

Throughout the specification, the term “feedback amplifier” is to be understood as an overall structure comprising various stages (preamplifier stage, error amplifier stage, etc.).

### BRIEF DESCRIPTION OF THE DRAWING

FIG. 1 is a block diagram of an existing feedback amplifier implemented by a BTL circuit;

FIG. 2 is a block diagram of another existing feedback amplifier having a current feedback circuit; and

FIG. 3 is a block diagram of a feedback amplifier having a current feedback circuit according to an embodiment of the present invention.

### DESCRIPTION OF THE PREFERRED EMBODIMENT

Now, an embodiment of the present invention will be described with reference to the drawings.

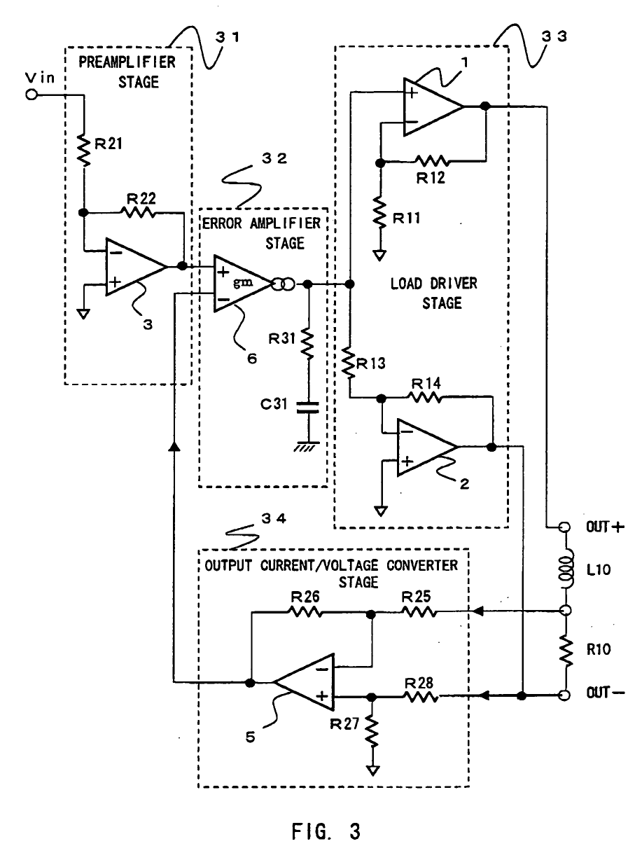

Referring to FIG. 3, a feedback amplifier with a current feedback circuit according to one embodiment of the present invention comprises a preamplifier stage 31, an error amplifier stage 32, a load driver stage 33, an output current/voltage converter stage 34, and a current detecting resistor R10. As a characteristic part of this invention, the current feedback circuit is formed by a combination of the output current/voltage converter stage 34 and the error amplifier stage 32. The output current/voltage converter stage 34 extracts an output current of the amplifier circuit through the current detecting resistor R10 and converts the output current into a voltage value as a feedback signal which is supplied to the error amplifier stage 32. The error amplifier stage 32 amplifies the input signal supplied from an input terminal Vin through the preamplifier stage 31 with reference to the feedback signal.

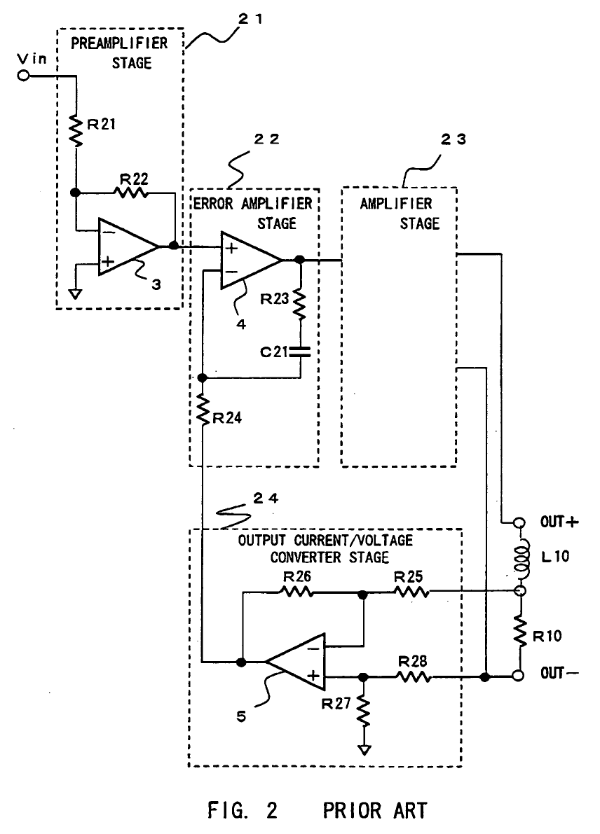

As compared with the existing feedback amplifier described in conjunction with FIG. 2, the amplifier circuit according to this invention is different in structure of the error amplifier stage 32. In other words, the remaining stages (31, 33, and 34) shown in FIG. 3 are similar in structure and function to the corresponding stages (21, 23, and 24) shown in FIG. 2.

The preamplifier stage 31 includes an operational amplifier 3 and resistors R21 and R22 and serves as an inverting amplifying circuit. The operational amplifier 3 has an inverting input terminal supplied with the input signal from the input terminal Vin through the resistor R21 and a non-inverting input terminal supplied with a predetermined voltage. The operational amplifier 3 has an output terminal connected to the error amplifier stage 32 and to the inverting input terminal of the operational amplifier 3 through the resistor R22. The operational amplifier 3 amplifies the input signal with reference to a feedback signal obtained through the resistor R22 and fed back to the inverting input terminal to produce a pre-amplified signal. The pre-amplified signal is delivered to the error amplifier stage 32 and to the inverting input terminal through the resistor R22 as the feedback signal.

The error amplifier stage 32 comprises a transconductance (gm) amplifier 6 with a resistor R31 and a capacitor C31 connected in series as a phase adjusting circuit. The transconductance amplifier 6 has a non-inverting input terminal connected to the output terminal of the preamplifier stage 31 and an inverting input terminal directly connected to the output terminal of the output current/voltage converter stage 34, and an output terminal connected to the load driver stage 33. One of the resistor R31 and the capacitor C31 as a series circuit is connected to the output terminal of the transconductance amplifier 6 and the other is connected to the ground potential.

The transconductance amplifier 6 is a so-called gm amplifier. However, the transconductance amplifier 6 may be replaced by any other differential amplifying circuit having an equivalent function as the voltage-controlled current-output type. It is noted here that a transfer function, of the error amplifier stage 32 is given by the product of an impedance of the series circuit comprising the resistor R31 and the capacitor C31 and the transconductance gm of the transconductance amplifier 6.

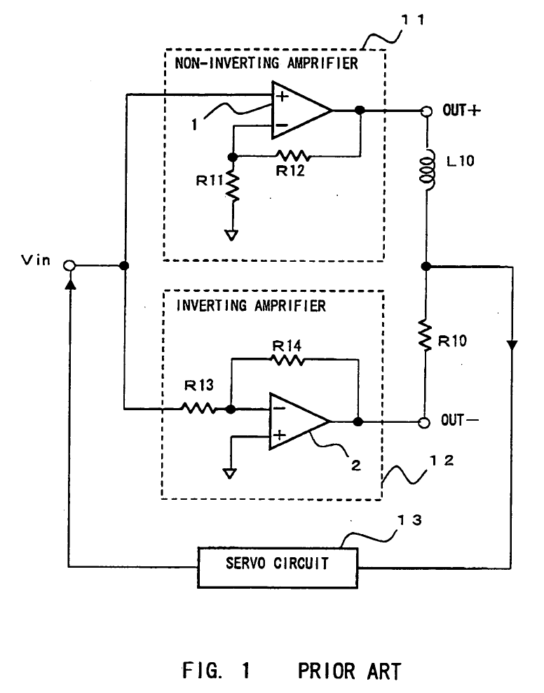

The load driver stage 33 is similar in structure to the circuit shown in FIG. 1, and comprises a combination of an operational amplifier 1 and resistors R11 and R12 as a non-inverting amplifier and another combination of an operational amplifier 2 and resistors R13 and R14 as an inverting amplifier. The operational amplifier 1 in the load driver stage 33 has an output terminal which serves as an output terminal OUT+ of the feedback amplifier. Likewise, the operational amplifier 2 in the load driver stage 33 has an output terminal which serves as an output terminal OUT− of the feedback amplifier. Between the output terminals OUT+ and OUT−, the coil load L10 and the current detecting resistor R10 are connected in series.

The output current/voltage converter stage 34 is similar in structure to the output current/voltage converter stage 24 shown in FIG. 2 and comprises a combination of an operational amplifier 5 and resistors R25 to R28 as a typical differential amplifier. Specifically, the operational amplifier 5 has an inverting input terminal which is connected through the resistor R25 to one end of the current detecting resistor R10 on the side of the output terminal OUT+ and which is also connected through the resistor R26 to an output terminal of the operational amplifier 5 to form a feedback circuit. Further, the operational amplifier 5 has a non-inverting input terminal which is connected through the resistor R27 to a predetermined voltage and which is also connected through the resistor R28 to the other end of the current detecting resistor R10 on the side of the output terminal OUT−. The output terminal of the operational amplifier 5 is directly connected to the inverting input terminal of the transconductance amplifier 6 in the error amplifier stage 32 to supply the feedback signal.

Continuously referring to FIG. 3, further description will be made of the error amplifier stage 32 as a characteristic part of the present invention.

As described above, the transconductance amplifier 6 used in the present invention forms a differential amplifying circuit which comprises, for example, a pair of transistors and a constant-current source and produces an output current given by a product of an input voltage and the transconductance gm. Accordingly, the transconductance amplifier 6 can be applied over a wider range of frequency band and has features as the differential amplifying circuit.

Furthermore, in case where the error amplifier stage 32, including the transconductance amplifier 6 and the peripheral resistor R31, is formed into an integrated circuit, the capacitor C31 is connected as an external component outside of the integrated circuit. In this case, the capacitor C31 requires an Independent input/output terminal at its one end. However, the other end of the capacitor C31 does not require such independent terminal but a ground terminal can be used in common. Accordingly, as compared with the circuit structure illustrated in FIG. 2 in which the other end of the capacitor is connected to the operational amplifier, the number of terminals in this invention is reduced. Thus, the present invention can contribute to miniaturization of the integrated circuit and a package accommodating the integrated circuit.

The above-described transconductance amplifier 6 in the error amplifier stage 32 may be replaced by different kinds of operational amplifiers of a voltage-controlled current-output type.

While the present invention has been described in detail in conjunction with the several preferred embodiments thereof, the present invention is not limited to the foregoing description but can be modified in various manners without departing from the scope of the invention set forth in appended claims.

What is claimed is:

1. A current feedback circuit for use in a feedback amplifier for producing an output voltage in response to an input signal, said current feedback circuit comprising an output current/voltage converter stage (34) for converting an electric current flowing through a current detecting resistor (R10) inserted on an output side of said feedback amplifier into a voltage to produce a feedback signal representative of the voltage and an error amplifier stage (32) supplied with the input signal and the feedback signal produced by said output current/voltage converter stage for amplifying the input signal with reference to the feedback signal to produce an amplified signal which is delivered to a load driver stage (33), wherein said error amplifier stage comprises:
an operational amplifier (6) of a voltage-controlled current-output type, supplied with the input signal and the feedback signal produced by said output current/voltage converter stage, for producing an amplified current obtained by amplifying the input signal with reference to the feedback signal;
a resistor (R31) connected between a ground potential and an output terminal of said operational-amplifier; and
a capacitor (C31) connected in series to said current detecting resistor between the ground potential and said output terminal of said operational amplifier.

2. A current feedback circuit according to claim 1, wherein said operational amplifier in said error amplifier stage is a transconductance amplifier for producing a current corresponding to a differential voltage between an inverting input terminal and a non-inverting input terminal thereof.

3. A current feedback circuit according to claim 2, wherein said transconductance amplifier is supplied with the input signal to the non-inverting input terminal thereof through a preamplifier stage (31) and with the output signal produced by said output current/voltage converter stage to the inverting input terminal thereof.

4. A feedback amplifier for producing a voltage in response to an input signal to supply a current for driving an external load, said feedback amplifier comprising:
a preamplifier stage (31) for pre-amplifying the input signal to produce a pre-amplified signal;
an output current/voltage converter stage (34) for converting an electric current flowing through a current detecting resistor (R10) inserted on an output side of said feedback amplifier into a feedback voltage to produce a feedback signal representative of the feedback voltage;
an error amplifier stage (32) supplied with the pre-amplified signal produced by said preamplifier stage and the feedback signal produced by said output current/voltage converter stage for amplifying the pre-amplified signal with reference to the feedback signal to produce an amplified signal; and
a load driver stage (33) supplied with the amplified signal produced by said error amplifier stage for producing the current which is supplied to the external load to drive the external load;
said error amplifier stage comprising:
an operational amplifier (6) of a voltage-controlled current-output type, supplied with the pre-amplified signal and the feedback signal, for producing an amplified current obtained by amplifying the pre-amplified signal with reference to the feedback signal;
a resistor (R31) connected between an output terminal of said operational amplifier in said error amplifier stage and a ground potential; and
a capacitor (C31) connected in series to said resistor between the ground potential and the output terminal of said operational amplifier in said error amplifier stage.

5. A feedback amplifier according to claim 4, wherein said operational amplifier in said error amplifier stage is a transconductance amplifier having a non-inverting input terminal supplied with the pre-amplified signal and an inverting input terminal supplied with the output signal produced by said output current/voltage converter stage, said operational amplifier being for producing a current corresponding to a differential voltage between the inverting and the non-inverting input terminals thereof.
